(19) United States
(12) Patent Application Publication
(10) Pub. No.: US 2025/0218958 A1
(43) Pub. Date: Jul. 3, 2025

(54) PEDESTALS FOR SEMICONDUCTOR COMPONENTS EMBEDDED IN PACKAGE SUBSTRATES AND RELATED METHODS

(71) Applicant: Intel Corporation, Santa Clara, CA (US)

(72) Inventors: Brandon Christian Marin, Gilbert, AZ (US); Bohan Shan, Chandler, AZ (US); Joseph Allen Van Nausdle, Chandler, AZ (US); Leonel Arana, Phoenix, AZ (US); Kyle Jordan Arrington, Gilbert, AZ (US); Xavier F. Brun, Hillsboro, OR (US); Ryan Joseph Carrazzone, Chandler, AZ (US); Ashay Dani, Chandler, AZ (US); Gang Duan, Chandler, AZ (US); Hongxia Feng, Chandler, AZ (US); Mohit Gupta, Chandler, AZ (US); Wei Li, Chandler, AZ (US); Ziyin Lin, Chandler, AZ (US); Yongki Min, Phoenix, AZ (US); Tyler Osborn, Sherwood, OR (US); Srinivas Venkata Ramanuja Pietambaram, Chandler, AZ (US); Teng Sun, Chandler, AZ (US); Jose Fernando Waimin Almendares, Gilbert, AZ (US); Dingying Xu, Chandler, AZ (US)

(21) Appl. No.: 18/398,847

(22) Filed: Dec. 28, 2023

(51) Int. Cl. H01L 23/538; H01L 21/48; H01L 23/00; H01L 23/64; H01L 25/065

(52) U.S. Cl. CPC H01L 23/5386; H01L 21/4846; H01L 23/5383; H01L 23/5384; H01L 23/642; H01L 24/32; H01L 24/16; H01L 25/0655; H01L 2224/16227; H01L 2224/32145

(57) ABSTRACT

Pedestals for semiconductors embedded in package substrates and related methods are disclosed. An example package substrate for an integrated circuit package disclosed herein includes core having a first surface, a second surface, and a cavity formed in the first surface, a semiconductor component disposed in the cavity, and a pedestal disposed in the cavity, the pedestal having a third surface coupled to the semiconductor component, and a fourth surface adjacent to the first surface, the pedestal dimensioned such that a first thickness of the pedestal and semiconductor is substantially equal to a second thickness of the core.

### FIELD OF THE DISCLOSURE

This disclosure relates generally to semiconductor packages and, more particularly, to pedestals for semiconductors embedded in package substrates and related methods.

### BACKGROUND

In many electronic devices, integrated circuit (IC) chips and/or semiconductor dies are connected to larger circuit boards such as motherboards and/or other types of printed circuit boards (PCBs) via a package substrate. Some known IC packages utilize voltage regulators for power delivery applications. In some instances, capacitors and/or other semiconductor components used for such voltage regulators can be included in the package substrate for an IC package.

### BRIEF DESCRIPTION OF THE DRAWINGS

FIG. 1 is a cross-sectional side view of an example integrated circuit (IC) package implemented in accordance with teachings disclosed herein.

FIG. 2 is a cross-sectional side view of an example package substrate implemented in accordance with teachings disclosed herein.

FIG. 3A is a cross-sectional side view of an example semiconductor component assembly including an example pedestal implemented in accordance with teachings disclosed herein.

FIG. 3B is a cross-sectional side view of the semiconductor component assembly of FIG. 3A embedded in a core of a package substrate.

FIG. 4A is a cross-sectional side view of another example semiconductor component assembly including an example pedestal composed of silicon.

FIG. 4B is a cross-sectional side view of another example semiconductor component assembly including another example pedestal composed of a filler material.

FIG. 4C is a cross-sectional side view of another example semiconductor component assembly including another example pedestal that includes another semiconductor component.

FIG. 5A is a cross-sectional side view of another example semiconductor component assembly embedded in a core of a package substrate via an adhesive layer.

FIG. 5B is a cross-sectional side view of another example semiconductor component assembly embedded in a core of a package substrate via an encapsulate layer.

FIGS. 6-15 are cross-sectional views depicting a package substrate including the semiconductor component assembly of FIG. 2 in various intermediate stages of manufacture.

FIG. 16 is a flowchart representative of an example manufacturing process for manufacturing the semiconductor component assembly of FIGS. 2 and/or 3B.

FIG. 17 is a flowchart representative of an example manufacturing process for manufacturing the semiconductor component assembly of FIGS. 5A and 5B.

FIG. 18 is a top view of a wafer and dies that may be included in an IC package constructed in accordance with teachings disclosed herein.

FIG. 19 is a cross-sectional side view of an IC device that may be included in an IC package constructed in accordance with teachings disclosed herein.

FIG. 20 is a cross-sectional side view of an IC device assembly that may include an IC package constructed in accordance with teachings disclosed herein.

FIG. 21 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

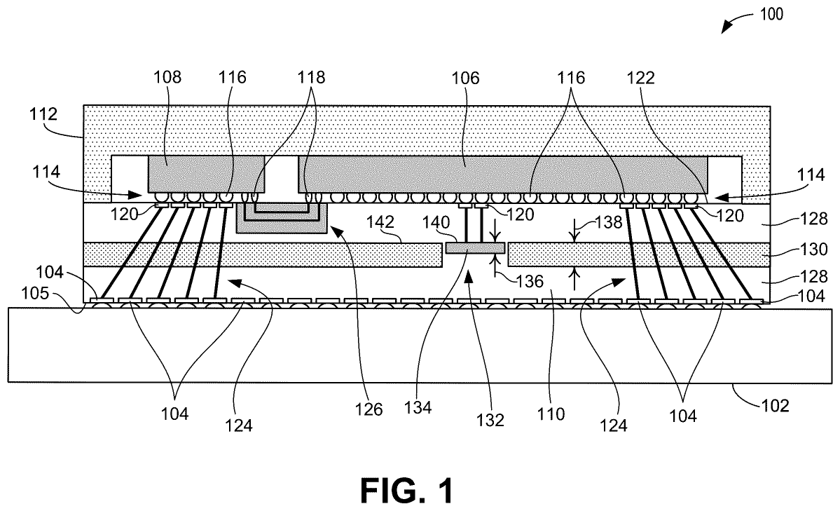

FIG. 1 illustrates an example integrated circuit (IC) package 100 constructed in accordance with teachings disclosed herein. In the illustrated example, the IC package 100 is electrically coupled to a circuit board 102 via an array of contact pads or lands 104 on a mounting surface 105 (e.g., a bottom surface) of the package. In some examples, the IC package 100 may include balls, pins, and/or pads, in addition to or instead of the contact pads 104, to enable the electrical coupling of the package 100 to the circuit board 102. In this example, the package 100 includes two semiconductor (e.g., silicon) dies 106, 108 (sometimes also referred to as chips or chiplets) that are mounted to a package substrate 110 and enclosed by a package lid or mold compound 112. Thus, the package substrate 110 is an example means for supporting a semiconductor die. While the example IC package 100 of FIG. 1 includes two dies 106, 108, in other examples, the package 100 may have only one die or more than two dies. In some examples, one of the dies 106, 108 (or a separate die) is embedded in the package substrate 110. The dies 106, 108 can provide any suitable type of functionality (e.g., data processing, memory storage, etc.).

As shown in the illustrated example, each of the dies 106, 108 is electrically and mechanically coupled to the substrate 110 via corresponding arrays of interconnects 114. In FIG. 1, the interconnects are shown as bumps. However, the interconnects 114 may be any other type of electrical connection in addition to or instead of the bumps shown (e.g., balls, pins, pads, wire bonding, etc.). The electrical connections between the dies 106, 108 and the substrate 110 (e.g., the interconnects 114) are sometimes referred to as first level interconnects. By contrast, the electrical connections between the IC package 100 and the circuit board 102 (e.g., the pads 104) are sometimes referred to as second level interconnects. In some examples, one or both of the dies 106, 108 may be stacked on top of one or more other dies and/or an interposer. In such examples, the dies 106, 108 are coupled to the underlying die and/or interposer through a first set of first level interconnects and the underlying die and/or interposer may be connected to the package substrate 110 via a separate set of first level interconnects associated with the underlying die and/or interposer. Thus, as used herein, first level interconnects refer to interconnects (e.g., balls, bumps, pins, pads, wire bonding, etc.) between a die and a package substrate or a die and an underlying die and/or interposer.

As shown in FIG. 1, the interconnects 114 of the first level interconnects include two different types of bumps corresponding to core bumps 116 and bridge bumps 118. As used herein, the core bumps 116 are bumps on the dies 106, 108 through which electrical signals pass between the dies 106, 108 and components external to the IC package 100. More particularly, as shown in the illustrated example, when the dies 106, 108 are mounted to the package substrate 110, the core bumps 116 are physically connected and electrically coupled to contact pads 120 on an inner surface 122 of the substrate 110. The contact pads 120 on the inner surface 122 of the package substrate 110 are electrically coupled to the pads 104 on the bottom (external) surface 105 of the substrate 110 (e.g., a surface opposite the inner surface 122) via internal interconnects 124 within the substrate 110. As a result, there is a continuous electrical signal path between the interconnects 114 of the dies 106, 108 and the pads 104 mounted to the circuit board 102 that pass through the contact pads 120 and the interconnects 124 provided therebetween.

As used herein, the bridge bumps 118 are bumps on the dies 106, 108 through which electrical signals pass between different ones of the dies 106, 108 within the package 100. Thus, as shown in the illustrated example, the bridge bumps 118 of the first die 106 are electrically coupled to the bridge bumps 118 of the second die 108 via an interconnect bridge 126 embedded in the package substrate 110. As represented in FIG. 1, core bumps 116 are typically larger than bridge bumps 118. In some examples, the interconnect bridge 126 and the associated bridge bumps 118 are omitted.

For purposes of illustration, the internal interconnects 124 are shown as straight lines extending directly between the pads 104 on the bottom surface 105 and the contact pads on the inner surface 122. However, in some examples, the internal interconnects 124 are defined by traces or routing in separate conductive (e.g., metal) layers within build-up regions 128 on one or both sides of a substrate core 130 in the package substrate 110. In such examples, the build-up regions 128 include dielectric layers to separate the different conductive layers. In such examples, the traces or routing in the different conductive layers are electrically coupled (to define the complete electrical path of the internal interconnects 124) by conductive (e.g., metal) vias extending between the different conductive layers. Further, in some examples, the internal interconnects 124 include vias that extend through the substrate core 130.

In some examples, the substrate core 130 is an organic substrate or core (e.g., an epoxy-based prepreg layer). In other examples, the substrate core 130 is a glass substrate or core. In some examples, glass substrates (e.g., the glass core 130) includes quartz, fused silica, and/or borosilicate glass. In some examples, glass substrates (e.g., the glass core 130) includes at least 20% (by weight) of each of silicon (Si) and oxygen (O). In other examples, glass substrates (e.g., the glass core 130) includes greater amounts of at least one of silicon or oxygen (e.g., at least 25 wt %, at least 30 wt %, at least 35 wt %, at least 40 wt %, etc.). In some examples, glass substrates (e.g., the glass core 130) includes at least 5% (by weight) of aluminum (Al). In accordance with the present disclosure, glass substrates (e.g., the glass core 130) include at least one glass layer and do not include epoxy and does not include glass fibers (e.g., does not include an epoxy-based prepreg layer with glass cloth). In some examples, glass substrates (e.g., the glass core 130) correspond to a single piece of glass that extends the full height/thickness of the core. In some examples, the glass core 130 has a rectangular shape that is substantially coextensive, in plan view, with the layers above and below the core (e.g., substantially coextensive with the build-up regions 128). The substrate core 130, whether an organic core or a glass core, provides stiffness and mechanical support or strength for the package substrate 110 and the rest of the package 100. Thus, the substrate core 130 is an example means for strengthening the package substrate 110. In some examples, the thickness of the core 130 is driven by the size (e.g., footprint) of the package 100. For example, in some instances, larger packages 100 include a substrate 110 with a larger (e.g., thicker) core as compared with smaller packages 100 where the core does not need to be as thick.

As shown in the illustrated example, the substrate core 130 includes a cavity 132 in which a semiconductor component 134 is embedded. In some examples, the semiconductor component 134 is a passive semiconductor die (e.g., a die that does not include transistors). In this example, the semiconductor component 134 is a deep trench capacitor die (also referred to herein as a deep trench capacitor, or simply capacitor, for short). In some such examples, the deep trench capacitor is used to enable efficient power delivery to a fully integrated voltage regulator within the first die 106 in the IC package 100. In other examples, other types of semiconductor components can be embedded within the cavity 132 of the substrate core 130 in addition to or instead of a deep trench capacitor. In some examples, more than one semiconductor component 134 can be embedded within the cavity 132 of the substrate core 130. In some examples, the substrate core 130 can include multiple cavities each containing one or more separate semiconductor components 134.

As noted above, in this example, the semiconductor component 134 is a deep trench capacitor and may be referred to as such herein. As shown in the illustrated example, the deep trench capacitor 134 is electrically coupled to the first die 106. In some examples, the deep trench capacitor 134 is positioned in close proximity to the first die 106 (e.g., within the substrate core 130 rather than spaced farther away like land-side capacitors) to reduce inductance and parasitic effects, thereby increasing the effectiveness of the deep trench capacitor 134 (and/or achieving a given capacitance with a smaller sized capacitor). However, a challenge with embedding a deep trench capacitor 134 within a core 130 of a substrate arises from the thickness mismatch between the deep trench capacitor 134 and the core 130. In this example, the deep trench capacitor 134 is constructed through wafer-level processing from a semiconductor (e.g., silicon) wafer. Due to the nature of such wafer-level processing, the deep trench capacitor 134 (e.g., the semiconductor component 134, etc.) has a thickness 136 limited to less than or equal to approximately 800 micrometers (μm) or less (e.g., less than or equal to approximately 700 μm, less than or equal to approximately 650 μm, less than or equal to approximately 600 μm, etc.). By contrast, the substrate core 130 can be significantly thicker, especially for larger packages as noted above. For instance, in some examples, the core 130 has a thickness 138 that is at least 20% greater than the thickness 136 of the deep trench capacitor 134 or more (e.g., at least 25% greater, at least 30% greater, at least 50% greater, at least 75% greater, at least twice as great, etc.). More specifically, in some examples, the thickness 138 of the core 130 is greater than approximately 800 μm or more (e.g., greater than or equal to approximately 900 μm, greater than or equal to approximately 1 millimeter (mm) (e.g., 1000 μm), greater than or equal to approximately 1.2 mm, greater than or equal to approximately 1.4 mm, greater than or equal to approximately 1.5 mm, etc.). Thus, as shown in FIG. 1, the thickness 136 of the deep trench capacitor 134 is less than the thickness 138 of the core 130.

The mismatch between the thicknesses 136, 138 of the deep trench capacitor 134 and the core 130 presents challenges in positioning the deep trench capacitor 134 within the cavity 132 of the core 130. Specifically, the relatively small size of the deep trench capacitor 134 can result in misalignments in any of the x, y, and z axes and/or rotational shifting or tilting because of the difficulty in securing the deep trench capacitor in place. In particular, the use of adhesives and/or an encapsulant to hold the deep trench capacitor 134 in place can be difficult because of the large space within the cavity 132 that needs to be filled which can result in a relatively long time for the adhesive and/or encapsulant to set or cure during which the deep trench capacitor 134 may shift, rotate, or otherwise move. As a result, a contact surface 140 of the deep trench capacitor 134 (e.g., a surface containing contacts with which the deep trench capacitor 134 is electrically coupled to (and facing towards) the first die 106) may not be aligned (e.g., flush) with a corresponding surface 142 (also facing towards the first die 106) of the substrate core 130. Such misalignment can negatively affect the ability of the deep trench capacitor 134 to electrically connect with the interconnects within the build-up region 128 above the core 130. Furthermore, the non-homogeneity of materials within the cavity 132 (e.g., the deep trench capacitor 134 and a relatively large volume of adhesive and/or encapsulant) can create processing challenges downstream and/or increase risks of warpage and/or mechanical stress in the package substrate 110.

Examples disclosed herein overcome the above challenges by providing a spacer, pedestal, platform, or other structure to fill much of the space within the cavity 132 and support the deep trench capacitor at a suitable height and at a suitable location relative to the core 130.

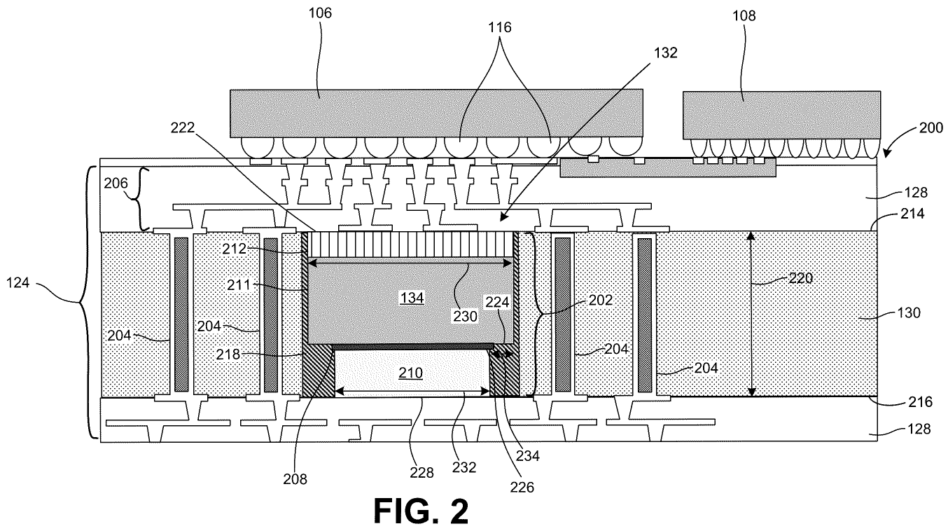

FIG. 2 is a cross-sectional side view of an example package substrate 200 implemented in accordance with teachings disclosed herein. In the illustrated example of FIG. 2, the package substrate 200 is similar to the package substrate 110 of FIG. 1, except that the package substrate 200 includes an example semiconductor component assembly 202 and as otherwise noted. In the illustrated example of FIG. 2, the package substrate 200 supports the first die 106 of FIG. 1 and the second die 108 of FIG. 1. In the illustrated example of FIG. 2, the package substrate 200 includes the internal interconnections 124 of FIG. 1, the build-up regions 128 of FIG. 1, the core 130 of FIG. 1, and the cavity 132 of FIG. 1. In the illustrated example of FIG. 2, the internal interconnections 124 includes example through core interconnections 204 (e.g., vias) and example build-up layer interconnections 206. In the illustrated example of FIG. 2, the semiconductor component assembly 202 includes the example semiconductor component 134 of FIG. 1, an example adhesive layer 208, and an example pedestal 210. In the illustrated example of FIG. 2, the semiconductor component 134 includes an example component die 211 and an example circuitry component 212. In the illustrated example of FIG. 2, the core 130 includes an example first core surface 214 and an example second core surface 216.

The core interconnections 204 extend through the core 130 and enable electric communication therethrough (e.g., between the circuit board 102 of FIG. 1 and the dies 106, 108, etc.). In some examples, the semiconductor component assembly 202 can also facilitate electric communication through the core 130. In some examples, the core interconnections 204 can be absent. The build-up layer interconnections 206 extend through the build-up regions 128. In the illustrated example of FIG. 2, the build-up layer interconnections 206 are in contact with the core interconnections 204, the dies 106, 108, and the circuitry component 212. The build-up layer interconnections 206 enable electric communication (1) between the dies 106, 108 and the semiconductor component 134; (2) the dies 106, 108; and (3) the core interconnections 204. The interconnections 204, 206 can be composed of any suitable conductive material, such as copper, silver, and/or another metal.

In the illustrated example of FIG. 2, the semiconductor component assembly 202 is disposed within the cavity 132 of the core 130. In the illustrated example of FIG. 2, the cavity 132 is filled with an example mold 218. In some examples, the mold 218 is a same material as the dielectric material in the build-up regions 128. Additionally or alternatively, the mold 218 can be any other insulative material including Ajinomoto build-up (ABF) film, a resin, a polymer, etc. In other examples, the mold 218 is absent. In the illustrated example of FIG. 2, the cavity 132 extends between the first core surface 214 and the second core surface 216 (e.g., the cavity 132 is a through hole, the cavity 132 is a through cavity, etc.) and has an example height 220. In the illustrated example of FIG. 2, the height 220 is the depth or thickness of the core 130. In other examples, the cavity 132 does not extend between the first core surface 214 and the second core surface 216. For example, the cavity 132 can be a blind hole formed in the first core surface 214 with a depth of the height 220 that is less than the depth or thickness of the core 130.

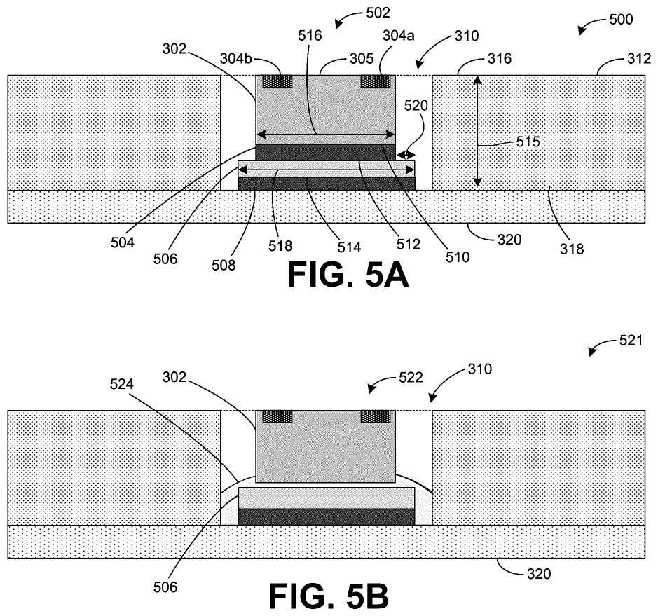

The adhesive layer 208 couples the pedestal 210 and the component die 211 of the semiconductor component 134. For example, the adhesive layer 208 can be a die attach film (DAF). In other examples, the adhesive layer 208 can be implemented via an encapsulant adhesive. An example semiconductor component assembly including an encapsulant adhesive is described below in conjunction with FIG. 5B. In some examples, the semiconductor component assembly 202 can include another adhesive layer (not illustrated in FIG. 2) (e.g., a second adhesive layer, etc.) that couples the pedestal 210 to the build-up regions 128 adjacent to the second core surface 216 of the core 130. Example semiconductor component assemblies including such a second adhesive layer are described below in conjunction with FIGS. 5A and 5B.

In the illustrated example of FIG. 2, the semiconductor component 134 is composed of the component die 211 and the circuitry component 212. The component die 211 is a silicon die that supports the circuitry component 212. That is, in some examples, the component die 211 corresponds to a diced portion of a base semiconductor (e.g., silicon) wafer on which the circuitry component 212 was fabricated prior to the wafer being diced. The circuitry component 212 is the electric component of the semiconductor component 134 that is formed on the component die 211. For example, the circuitry component 212 can include one or more capacitors (e.g., the semiconductor component 134 is a DTC, etc.). Additionally or alternatively, the circuitry component 212 can include other electrical components, such as one or more inductors. In some examples, the circuitry component 212 can include one or more pads, which facilitate electrical communication with other components of an IC package including the package substrate 200 via the build-up layer interconnections 206.

The semiconductor component assembly 202 supports the semiconductor component 134 and enables electrical communication between the semiconductor component 134 and the dies 106, 108. In the illustrated example of FIG. 2, the semiconductor component assembly 202 has a thickness substantially equal to the height 220 (e.g., the semiconductor component assembly 202 is the same thickness, the height 220, as the cavity 132, etc.). As used herein, two dimensions are “substantially equal” when the quantities are within 5 micrometers. That is, the sum of the vertical dimensions of the components of the semiconductor component assembly 202 is approximately equal to the height 220 of the cavity 132 (e.g., the sum of the thickness of the adhesive layer 208, the thickness of the pedestal 210, and the thickness of the semiconductor component 134, etc.).

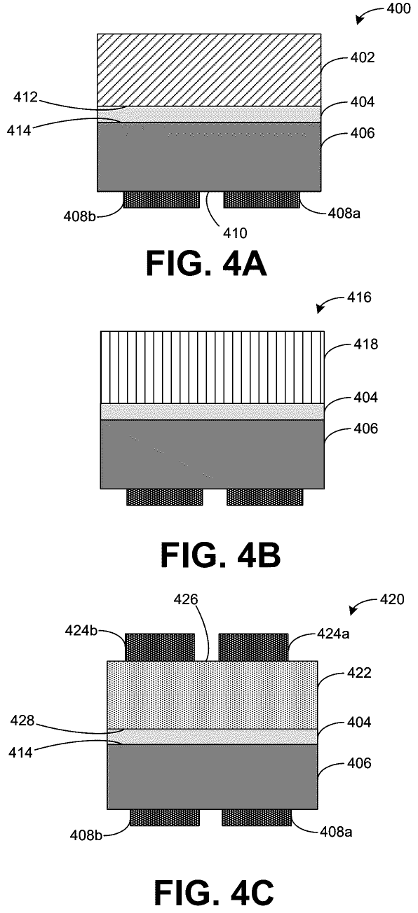

In the illustrated example of FIG. 2, the pedestal 210 is a spacer (e.g., a platform, etc.) that mitigates the mismatch in thickness between the semiconductor component 134 and the height 220 of the cavity 132. To enable the semiconductor component assembly 202 to have the height 220, the pedestal 210 can be dimensioned (e.g., manufactured, etc.) based on the size of the semiconductor component 134 relative to the size of the core 130. The pedestal 210 can be composed of any suitable material. For example, the pedestal 210 can include (e.g., be composed of, etc.) a silicon die (e.g., a dummy die, etc.). An example semiconductor component assembly including a pedestal including a silicon die is described below in conjunction with FIG. 4A. Additionally or alternatively, the pedestal 210 can include an insulative filler material. An example semiconductor component assembly including a pedestal composed of a filler material is described below in conjunction with FIG. 4B. Additionally or alternatively, the pedestal 210 cab include another semiconductor component (e.g., a DTC, etc.). An example semiconductor component assembly including a pedestal that includes a second semiconductor component is described below in conjunction with FIG. 4C.

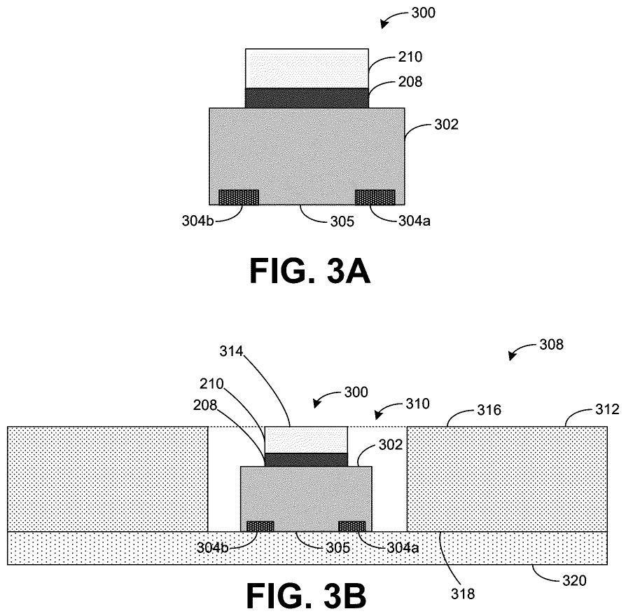

In the illustrated example of FIG. 2, the semiconductor component 134 includes an example first component surface 222 and an example second component surface 224 that is opposite to the first component surface 222. In the illustrated example of FIG. 2, the first component surface 222 is a top surface of the semiconductor component 134 and the circuitry component 212. In the illustrated example of FIG. 2, the pedestal 210 has an example first pedestal surface 226 and an example second pedestal surface 228 that is opposite to the first pedestal surface 226. In the illustrated example of FIG. 2, the first component surface 222 is substantially flush (e.g., within a tilt of 5 degrees or less, offset by less than 100 μm, etc.) with the first core surface 214 of the core 130. The flush relationship (e.g., coplanar relationship, etc.) between the first component surface 222 and the first core surface 214 of the core 130 facilitates the formation of the build-up layer interconnections 206 and electrical communications between the dies 106, 108 and the semiconductor component 134. In the illustrated example of FIG. 2, the second component surface 224 is adjacent to the first pedestal surface 226 and is coupled thereto via the adhesive layer 208. In the illustrated example of FIG. 2, the second pedestal surface 228 is substantially flush with the second core surface 216 of the core 130. In other examples, depending on the assembly and orientation of the semiconductor component assembly 202, the pedestal 210 and the semiconductor component 134 can have other geometric and spatial relationships. Example semiconductor component assemblies including pedestals and the semiconductor component in different configurations are described below in conjunction with FIGS. 3A-5B.

In the illustrated example of FIG. 2, the semiconductor component 134 has an example first width 230 and the pedestal 210 has an example second width 232. In the illustrated example, the first width 230 is greater than the second width 232 by an example offset 234 (e.g., the first width 230 is different than the second width 232, etc.). That is, in the illustrated example of FIG. 2, the semiconductor component 134 overhangs the pedestal 210 via the offset 234. In some examples, the offset 234 (e.g., the greater magnitude of the first width 230 compared to the second width 232, etc.) facilitates the coupling of the pedestal 210 to the semiconductor component 134 prior to the deposition of the semiconductor component assembly 202 within the cavity 132. For example, the offset 234 facilitates the alignment of pedestal 210 on the second component surface 224 of the semiconductor component 134 (e.g., the centering of the pedestal 210 on the second component surface 224, etc.).

It should be appreciated that the semiconductor component 134 and the pedestal 210 have another dimension (not illustrated), which extends perpendicularly from the widths 230, 232 and the height 220. As used herein, this dimension (e.g., into and out of the drawing shown in FIG. 2) is referred to as “a length.” As used herein, the term “planar area” is used to describe the area of components in a plane defined by the length and width of the component. In some examples, the length of the semiconductor component 134 is greater than or equal to the length of the pedestal 210. In such examples, the planar area of the component surfaces 222, 224 (e.g., a first planar area, etc.) is greater than the area of the pedestal surfaces 226, 228 (e.g., a second area, etc.). In other examples, the planar area of the component surfaces 222, 224 (e.g., a first planar area, etc.) is less than or equal to the area of the pedestal surfaces 226, 228 (e.g., a second planar area, etc.). In some such examples, the pedestal 210 can be disposed within the cavity 132 prior to the coupling of the semiconductor component 134 thereto. Example package substrates including such a semiconductor component assembly are described below in conjunction with FIGS. 5A and 5B.

FIG. 3A is a cross-sectional side view of another example semiconductor component assembly 300 prior to the deposition of the semiconductor component assembly 300 within a package substrate. In the illustrated example of FIG. 3, the semiconductor component assembly 300 includes the adhesive layer 208 of FIG. 2 and the pedestal 210 of FIG. 2. The example semiconductor component assembly 300 is similar to the semiconductor component assembly 202 of FIG. 2, except that the semiconductor component assembly 300 includes an example semiconductor component 302, which is oriented below the pedestal 210 (e.g., the semiconductor component assembly 300 has a pedestal-up configuration, etc.). The semiconductor component 302 of FIG. 3 is similar to the semiconductor component 134 except that the semiconductor component 302 includes an example first pad 304a and an example second pad 304b. In some examples, the semiconductor component 134 can include pads similar to the pads 304a, 304b of FIG. 3A (e.g., as part of the circuitry component 212, etc.).

The pads 304a, 304b are contact pads (e.g., lands, etc.) that enable electrical communication (e.g., electrical signals, etc.) with the semiconductor component 302. For example, the pads 304a, 304b can be electrically coupled to the circuitry components of the semiconductor component 302 (e.g., the circuitry components 212 of FIG. 2, etc.). In the illustrated example of FIG. 3A, the pads 304a, 304b are flush with an example first component surface 305 of the semiconductor component 302. That is, the pads 304a, 304b are embedded in the semiconductor component 302, such that the contact surfaces of the pads 304a, 304b are flush with the first component surface 305. In other examples, the pads 304a, 304b can extend from the first component surface 305 away from the semiconductor component 302. In other examples, the pads 304a, 304b can be recessed relative to the first component surface 305.

FIG. 3B is a cross-sectional schematic side view of the semiconductor component assembly 300 of FIG. 3A disposed within an example package substrate 308. In the illustrated example of FIG. 3B, the semiconductor component assembly 300 is embedded in an example cavity 310 of an example core 312 of the package substrate 308. In the illustrated example of FIG. 3B, the package substrate 308, the core 312, and the cavity 310 are similar to the package substrate 200 of FIG. 2, the core 130 of FIG. 2, and the cavity 132 of FIG. 2, respectively, except as noted otherwise. In the illustrated example of FIG. 3B, the pedestal 310 has an example pedestal surface 314. In the illustrated example of FIG. 3B, the core 312 includes an example first core surface 316 and an example second core surface 318 that is opposite to the first core surface 316. In the illustrated example of FIG. 3B, the package substrate 308 includes an example carrier 320.

The carrier 320 supports the semiconductor component assembly 300 during the manufacturing and assembling of the semiconductor component assembly 300 and the package substrate 308. For example, the carrier 320 can be a temporary carrier film (TCF). In other examples, the carrier 320 can be a polyimide or other polymer film. Additionally or alternatively, the carrier 320 can include a cured epoxy laminate. In some examples, the carrier 320 has a thickness of between 10 and 1000 microns. In some examples, after the deposition of the semiconductor component assembly 300 within the cavity 310 of the package substrate 308, the filling of the cavity 310, and/or the deposition of a build layer on the first core surface 316, the carrier 320 can be removed. In some examples, the removal of the carrier 320 enables the deposition of material (e.g., build-up layers, etc.) on the second core surface 318.

In the illustrated example of FIG. 3B, the semiconductor component assembly 300 is disposed within the cavity 310. Like the semiconductor component assembly 202 of FIG. 2, the pedestal 210 is dimensioned such that the semiconductor component assembly 300 has a same thickness as the depth of the cavity 310. In the illustrated example of FIG. 3B, the pedestal surface 314 is substantially flush with the first core surface 316. In the illustrated example of FIG. 3B, the first component surface 305 and the pads 304a, 304b are substantially flush with the second core surface 318 and abut the carrier 320. In other examples, if the pads 304a, 304b extend from the first component surface 305, the bottoms of the pads 304a, 304b abut the carrier 320 and are substantially flush with the second core surface 318. In some such examples, the first component surface 305 is spaced from the second core surface 318 and the carrier 320. In other examples, the semiconductor component assembly 300 can be flipped (e.g., rotated 180 degrees, etc.), such that the pedestal 210 is below the semiconductor component 302 (e.g., in an orientation similar to the orientation of the semiconductor component assembly 202 of FIG. 2, in a pedestal-down configuration, etc.).

FIG. 4A is a cross-sectional side view of another example semiconductor component assembly 400 including an example first pedestal 402. In the illustrated example of FIG. 4, the semiconductor component assembly 400 semiconductor component assembly 400 includes an example adhesive layer 404 and an example semiconductor component 406. The semiconductor component 406 is similar to the semiconductor component 302 of FIG. 3, except that the semiconductor component 406 includes an example first pad 408a and an example second pad 408b, which extend from an example adjacent surface 410 of the semiconductor component 406. The adhesive layer 404 is similar to the adhesive layer 208 of FIGS. 2 and 3, except that the adhesive layer 404 extends along the entire planar area of an example pedestal surface 412 of the first pedestal 402 and the example component surface 414 of the semiconductor component 406. In other examples, if the pedestal surface 412 and the component surface 414 have different areas (e.g. have an offset similar to the offset 234 of FIG. 2, etc.), the adhesive layer 404 can be sized based on the smaller area of the pedestal surface 412 and the component surface 414. In the illustrated example of FIG. 4A, the first pedestal 402 is composed of silicon. For example, the first pedestal 402 can be a dummy die (e.g., a die that does not include circuits formed thereon, etc.) and/or any other suitable silicon component. Like the pedestal 210 of FIGS. 2 and 3, the thickness of the first pedestal 402 (e.g., the height of the first pedestal 402, etc.) can be dimensioned based on the thickness of the core that is to receive the semiconductor component assembly 400 semiconductor component assembly 400 (e.g., the core 130 of the package substrate 200 of FIG. 2, the core 312 of the package substrate 308 of FIG. 3B, etc.).

FIG. 4B is a cross-sectional side view of another example semiconductor component assembly 416 including an example second pedestal 418. The semiconductor component assembly 416 includes the adhesive layer 404 of FIG. 4A and the semiconductor component 406 of FIG. 4A. In the illustrated example of FIG. 4B, the second pedestal 418 is composed of a filler material. In some examples, the second pedestal can be applied via direct dispense method (e.g., the method used for underfill, etc.). In other examples, the second pedestal can be laminated with the adhesive layer 404 and the semiconductor component 406 as a single piece. For example, the second pedestal 418 can be composed of a polymer, an epoxy resin, a composite (e.g., pre-preg, etc.), and/or any other suitable non-conductive material. Like the pedestal 210 of FIGS. 2 and 3, the thickness of the second pedestal 418 (e.g., the height of the second pedestal 418, etc.) can be dimensioned based on the thickness of the core that is to receive the semiconductor component assembly 416 (e.g., the core 130 of the package substrate 200 of FIG. 2, the core 312 of the package substrate 308 of FIG. 3B, etc.).

The first pedestal 402 of FIG. 4A and the second pedestal 418 of FIG. 4B can be selected based on the desired thermal and/or mechanical properties of the package substrate including one or more of the semiconductor component assemblies 400, 416. For example, the first pedestal 402 has comparatively increased stiffness when compared to the second pedestal 418. Similarly, the first pedestal 402 can have comparatively more or less thermal conductivity when compared to the second pedestal 418.

FIG. 4C is a cross-sectional side view of an example semiconductor component assembly 420 including an example third pedestal 422. The third semiconductor component assembly 420 includes the adhesive layer 404 of FIGS. 4A and 4B and the semiconductor component 406 of FIGS. 4A and 4B. In the illustrated example of FIG. 4C, the third pedestal 422 is a semiconductor component that is similar to the semiconductor component 134 of FIGS. 1 and 2 and/or the semiconductor component 406 of FIGS. 4A and 4B. For example, the third pedestal 422 can include one or more DTCs or similar semiconductor components (e.g., inductors, etc.). In some examples, the third pedestal 422 can be implemented by a same semiconductor component as the semiconductor component 406.

In the illustrated example of FIG. 4C, the third pedestal 422 includes an example third pad 424a and an example fourth pad 424b. In the illustrated example of FIG. 4C, the pads 424a, 424b extend from an example first pedestal surface 426. In other examples, the pads 424a, 424b can be embedded within the third pedestal 422 and substantially flush with (or recessed relative to) the first pedestal surface 426. The pads 424a, 424b can be electrically coupled to interconnects of a package substrate (e.g., the build-up layer interconnects 206 of FIG. 2, etc.) opposite the connection formed between the pads 408a, 408b of the semiconductor component 406 and corresponding interconnections of the package substrate. For example, if the third semiconductor component assembly 420 is to be disposed within the cavity 132 of FIG. 2, the pads 424a, 424b can be flush with the second core surface 216 of FIG. 2. In the illustrated example of FIG. 4C, the third pedestal 422 includes an example second pedestal surface 428, which abuts the adhesive layer 404. The adhesive layer 404 couples the third pedestal 422 to the semiconductor component 406.

FIG. 5A is a cross-sectional side view of an example package substrate 500 including another example semiconductor component assembly 502. In the illustrated example of FIG. 5A, the package substrate 500 is similar to the package substrate 308 of FIG. 3B, except that the package substrate 500 includes the semiconductor component assembly 502 and as noted otherwise. In the illustrated example of FIG. 5, the package substrate 500 includes the example core 312 and the example carrier 320. In the illustrated example of FIG. 5A, the semiconductor component assembly 502 includes the semiconductor component 302 of FIGS. 3A and 3B, an example first adhesive layer 504, an example pedestal 506, and an example second adhesive layer 508. The semiconductor component 302 includes the example pads 304a, 304b of FIGS. 3A and 3B and the first component surface 305 of FIGS. 3A and 3B and an example second component surface 510. In the illustrated example of FIG. 5A, the pedestal 506 includes an example first pedestal surface 512 and an example second pedestal surface 514.

The adhesive layers 504, 508 are similar to the adhesive layer 208 of FIG. 2B. For example, the adhesive layers 504, 508 can be implemented by a die attach film (DAF). In other examples, the adhesive layers 504, 508 can be implemented by any other suitable structure and/or material. The pedestal 506 increases the thickness of the semiconductor component assembly 502. For example, the pedestal 506 can be dimensioned to increase the thickness of the semiconductor component assembly 502 to be equal to an example thickness 515 of the cavity 310, such that the first component surface 305 is substantially flush with the first core surface 316. That is, the sum of the vertical dimensions of the components of the semiconductor component assembly 502 is approximately equal to the thickness 515 of the cavity 310 (e.g., the sum of the thickness of the adhesive layers 504, 508, the thickness of the pedestal 506, and the thickness of the semiconductor component 302, etc.). The pedestal 506 can be implemented by a pedestal similar to the pedestal 210 of FIGS. 2-3B, the first pedestal 402 of FIG. 4A (e.g., a dummy silicon die, etc.), and the second pedestal 418 of FIG. 4B (e.g., filler material, etc.).

The carrier 320 supports the semiconductor component assembly 502. In the illustrated example of FIG. 5, the second adhesive layer 508 is disposed between and couples the pedestal 506 to the carrier 320. The pedestal 506 is disposed between the first adhesive layer 504 and the second adhesive layer 508. The first adhesive layer 504 couples the pedestal 506 to the semiconductor component 302. The carrier 320 can be removed during the manufacturing and/or assembly of the package substrate 500.

In the illustrated example of FIG. 5A, the semiconductor component 134 has an example first width 516 and the pedestal 506 has an example second width 518. In the illustrated example, the second width 518 is greater than the first width 516 by an example offset 520 (e.g., the first width 516 is different than the second width 518, etc.). In the illustrated example of FIG. 5A, the pedestal 506 overhangs the semiconductor component 302 via the offset 520. The offset 520 facilitates the coupling of the semiconductor component 302 prior to the deposition of the semiconductor component assembly 502 within the cavity 310. For example, the offset 520 facilitates the alignment of the second component surface 510 to the first pedestal surface 512 (e.g., the centering of the semiconductor component 302 on the pedestal 506, etc.). In other examples, the semiconductor component assembly 502 can be assembled within the cavity 310. For example, the pedestal 506 can be disposed within the cavity 310 and coupled to the carrier 320 via the second adhesive layer 508. After the disposition of the pedestal 506, the semiconductor component 302 can be coupled to the pedestal 506 via the first adhesive layer 504. In some examples, the first adhesive layer 504 can be formed on the first pedestal surface 512 after the positioning of the pedestal 506 within the cavity 310. In other examples, the first adhesive layer 504 can be formed on the pedestal prior to the positioning thereof within the cavity 310. It should be appreciated that the semiconductor component 134 and the pedestal 506 have lengths (not illustrated), which extend perpendicularly from the widths 516, 518 and the thickness 515. In some examples, the length of the semiconductor component 134 is less than or equal to the length of the pedestal 506. In such examples, the planar area of the component surfaces 305, 510 (e.g., a first planar area, etc.) is less than the area of the pedestal surfaces 512, 514 (e.g., a second planar area, etc.). That is, unlike the semiconductor component assembly 202 of FIG. 2 and the semiconductor component assembly 300 of FIGS. 3A and 3B, the planar area of the pedestal surfaces 512, 514 is greater than the planar area of the component surfaces 305, 510.

FIG. 5B is a cross-sectional side view of an example package substrate 521 including another example semiconductor component assembly 522. The package substrate 521 and the semiconductor component assembly 522 are similar to the package substrate 500 of FIG. 5A and the semiconductor component assembly 502 of FIG. 5A, except that the first adhesive layer 504 has been replaced by an encapsulate layer 524. The encapsulate layer 524 couples the pedestal 506 to the semiconductor component 302. During the assembly of the package substrate 521 and the semiconductor component assembly 522, the encapsulate layer 524 can be deposited (e.g., via jetting, etc.) on the pedestal 506 and within the cavity 310.

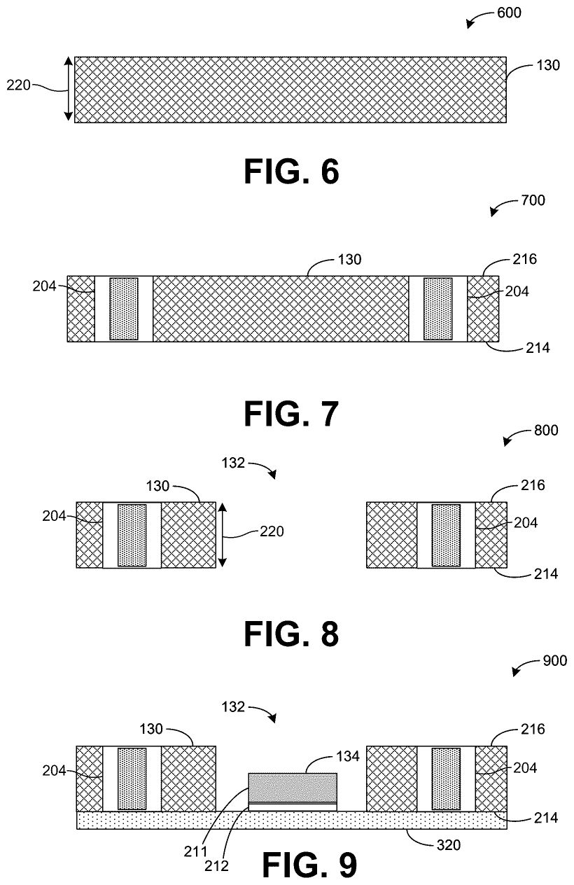

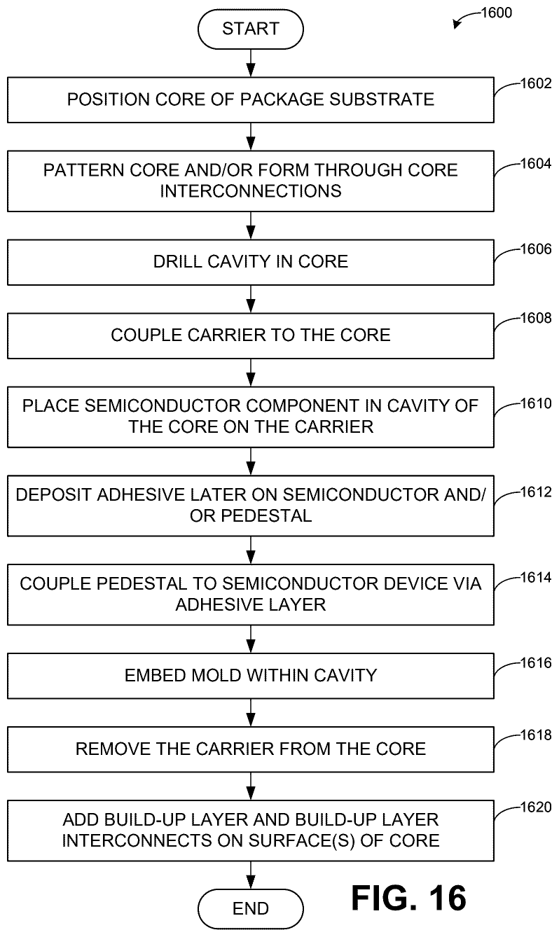

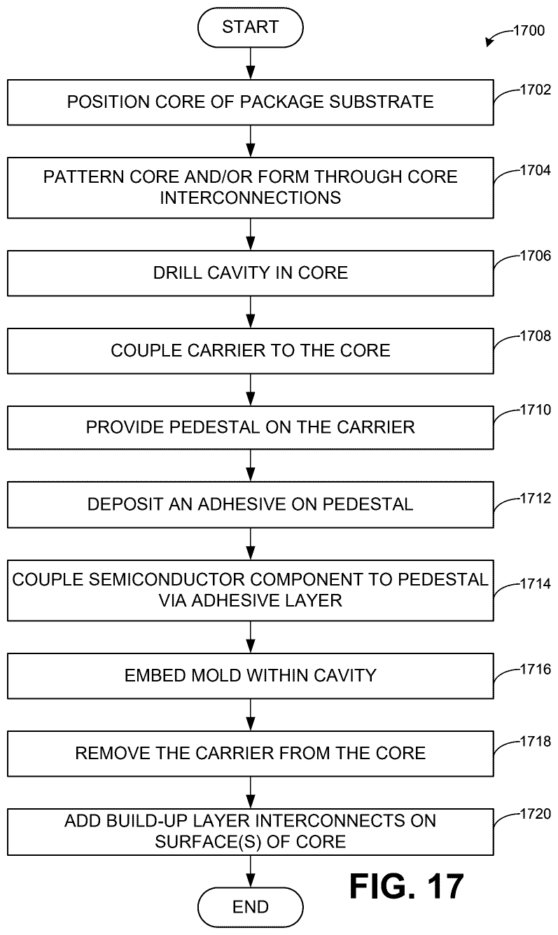

FIGS. 6-15 depict a plurality of intermediate stages in an example process to manufacture the package substrate 200 of FIG. 2. In some examples, the package substrate 308 of FIG. 3B can be manufactured via an example process similar to the process associated with the intermediate stages of FIGS. 6-15 (e.g., by omitting the execution of the intermediate stage of FIG. 14, etc.). In other examples, an assembly similar to the package substrate 500 of FIG. 5A and/or the package substrate 521 of FIG. 5B can be manufactured via a process that includes intermediate stages different than the ones illustrated in conjunction with FIGS. 6-15. It should be appreciated that other processes can be used to manufacture the package substrate 200 of FIG. 2 and/or the package substrate 308 of FIG. 3B. Example operations to manufacture the package substrate 200 of FIG. 2 and/or the package substrate 308 of FIG. 3B via the intermediate stages of FIGS. 6-15 are described below in conjunction with FIG. 16. Example operations to manufacture the package substrate 500 of FIG. 5A and/or the package substrate 521 of FIG. 5B are described below in conjunction with FIG. 17.

FIG. 6 is a cross-sectional view of an example first intermediate stage 600 of the assembly/manufacturing of the package substrate 200 including the semiconductor component assembly 202. During the first intermediate stage 600, the core 130 is provided. For example, a core 130 can be positioned onto and/or within a die fabrication system. In the illustrated example of FIG. 6, the core 130 has a thickness equal to the height 220. In some examples, the core 130 can be manufactured with a thickness equal to the height 220. In other examples, the thickness of the core 130 can be reduced (e.g., via planarization, etc.) to the height 220. In some examples, the core 130 is a glass core. In other examples, the core 130 can be composed of any other suitable material (e.g., epoxy-based prepreg, silicon, germanium, selenium, tellurium, etc.).

FIG. 7 is a cross-sectional view of an example second intermediate stage 700 of the assembly/manufacturing of the package substrate 200 including the semiconductor component assembly 202. In some examples, the second intermediate stage 700 occurs after the first intermediate stage 600 of FIG. 6. In the second intermediate stage 700, the core 130 has been patterned to form the through core interconnections 204 therethrough. In the illustrated example of FIG. 7, the through core interconnections 204 extend between the first core surface 214 of the core 130 and the second core surface 216 of the core 130. In some examples, the core 130 can be patterned via laser etching, drilling, wet etching, and/or any other suitable manufacturing process. In some examples, after the patterning of the core 130, the core interconnections 204 can be formed via electroplating, atomic layer deposition (ALD), chemical vapor deposition (CVD), physical vapor deposition (PVD), etc. In the illustrated example of FIG. 7, the core 130 includes two of the core interconnections 204. In other examples, the core 130 can include any suitable number of core interconnections. In some examples, if the core 130 is a glass core, the through core interconnections 204 can be through glass vias (TGVs). In the illustrated examples of FIGS. 7-13, the core surfaces 214, 216 have the reversed orientation (e.g., the first core surface 214 is below the second core surface 216, etc.) compared to the orientation of FIG. 2. It should be appreciated that the package substrate is flipped (e.g., rotated 180 degrees, etc.) after the intermediate step of FIG. 14.

FIG. 8 is a cross-sectional view of an example third intermediate stage 800 of the assembly/manufacturing of the package substrate 200 including the semiconductor component assembly 202. In some examples, the third intermediate stage 800 occurs after the second intermediate stage 700. In the third intermediate stage 800, the cavity 132 of FIG. 1 has been formed in the core 130. For example, the cavity 132 can be formed in the core 130 via drilling. In other examples, the cavity 132 can be formed via any other suitable material removal process (e.g., laser etching, wet etching, etc.). In the illustrated example of FIG. 8, the cavity 132 has a depth equal to the height 220 (e.g., the cavity 132 is a through hole that extends between the core surfaces 214, 216, etc.). In other examples, the cavity 132 can be a blind hole.

FIG. 9 is a cross-sectional view of an example fourth intermediate stage 900 of the assembly/manufacturing of the package substrate 200 including the semiconductor component assembly 202. In some examples, the fourth intermediate stage 900 occurs after the third intermediate stage 800. In the fourth intermediate stage 900, the carrier 320 has been attached to the first core surface 214 of the core 130 and the semiconductor component 134 has been disposed within the cavity 132 onto the carrier 320. In the illustrated example of FIG. 9, the carrier 320 is a temporary carrier film (TCF) that can be coupled to the first core surface 214 of the core 130 as a die attach film. In other examples, the core 130 can be placed on the carrier 320. In the illustrated example of FIG. 9, the semiconductor component 134 has been placed within the cavity 132 such that the circuitry component 212 is adjacent (e.g., faces towards) the carrier 320 to be substantially flush with the first core surface 214 (e.g., the semiconductor component 134 has been placed die side-up, etc.). In some examples, the circuitry component 212 can include pads (e.g., similar to the pads 304a, 304b of FIGS. 3A and 3B, etc.) that enable electric component with external components (e.g., the dies 106, 108 of FIG. 1, etc.). In the illustrated example of FIG. 9, the pedestal 210 is to be coupled to the semiconductor component 134. In other examples, the first pedestal 402 of FIG. 4A, the second pedestal 418 of FIG. 4B, and/or the third pedestal 422 of FIG. 4C can alternatively be coupled to the semiconductor component 134.

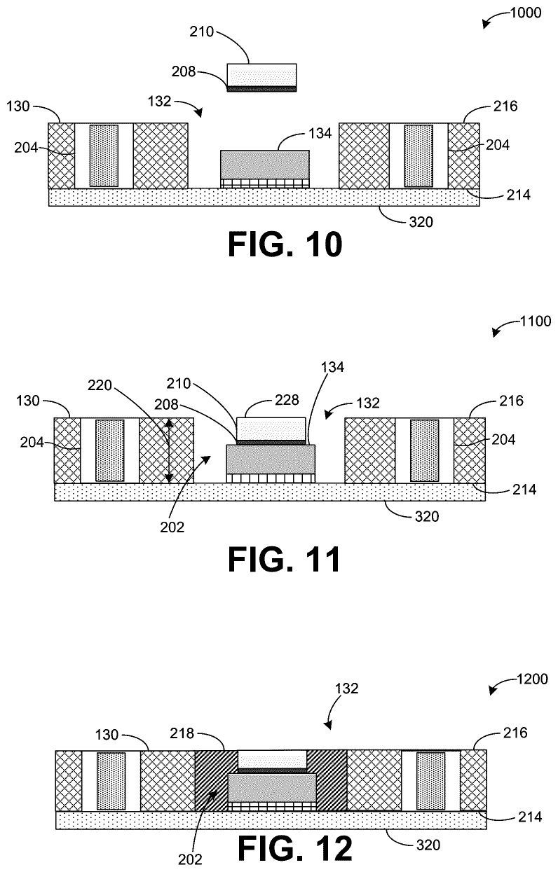

FIG. 10 is a cross-sectional view of an example fifth intermediate stage 1000 of the assembly/manufacturing of the package substrate 200 including the semiconductor component assembly 202. In some examples, the fifth intermediate stage 1000 occurs after the fourth intermediate stage 900. In the fifth intermediate stage 1000, the adhesive layer 208 has been coupled to the pedestal 210 to prepare the pedestal 210 for coupling to the semiconductor component 134 within the cavity 132. The adhesive layer 208 can be coupled to the pedestal 210 via a die attach film (DAF). In other examples, the adhesive layer 208 can be coupled to the semiconductor component 134. In some such examples, the adhesive layer 208 can be coupled to the semiconductor component 134 prior to the positioning of the semiconductor component 134 within the cavity 132. In some examples, the adhesive layer 208 can be omitted. In some such examples, an encapsulate adhesive (e.g., similar to the encapsulate layer 524 of FIG. 5B, etc.) can be deposited within the cavity 132 onto the semiconductor component 134 and used to couple the pedestal 210 to the semiconductor component 134.

FIG. 11 is a cross-sectional view of example sixth intermediate stage 1100 of the assembly/manufacturing of the package substrate 200 including the semiconductor component assembly 202. In some examples, the sixth intermediate stage 1100 occurs after the fifth intermediate stage 1000. The sixth intermediate stage 1100 includes the coupling of the pedestal 210 to the semiconductor component 134 via the adhesive layer 208. In the illustrated example of FIG. 11, the second pedestal surface is substantially flush with the second core surface 216. The coupling of the pedestal 210 to the semiconductor component 134 forms the semiconductor component assembly 202 of FIG. 2. In the illustrated example of FIG. 11, the semiconductor component assembly 202 has the height 220 and is equal to the depth of the cavity 132.

FIG. 12 is a cross-sectional view of an example seventh intermediate stage 1200 of the assembly/manufacturing of the package substrate 200 including the semiconductor component assembly 202. In some examples, the seventh intermediate stage 1200 occurs after the sixth intermediate stage 1100. In the seventh intermediate stage 1200, the cavity 132 has been filled with the mold 218. That is, the mold 218 has been embedded within the cavity 132. In the illustrated example of FIG. 12, the mold 218 is substantially flush with core surfaces 214, 216. In other examples, the mold 218 can extend over the second core surface 216. In the illustrated example of FIG. 12, the mold 218 surrounds the semiconductor component assembly 202 (e.g., the mold 218 surrounds the semiconductor component 134, etc.). In some examples, the mold 218 can be ABF deposited via lamination. In other examples, the mold 218 can be composed of any other suitable material(s). Additionally or alternatively, the mold 218 can be deposited via electroplating, atomic layer deposition (ALD), chemical vapor deposition (CVD), physical vapor deposition (PVD), etc.

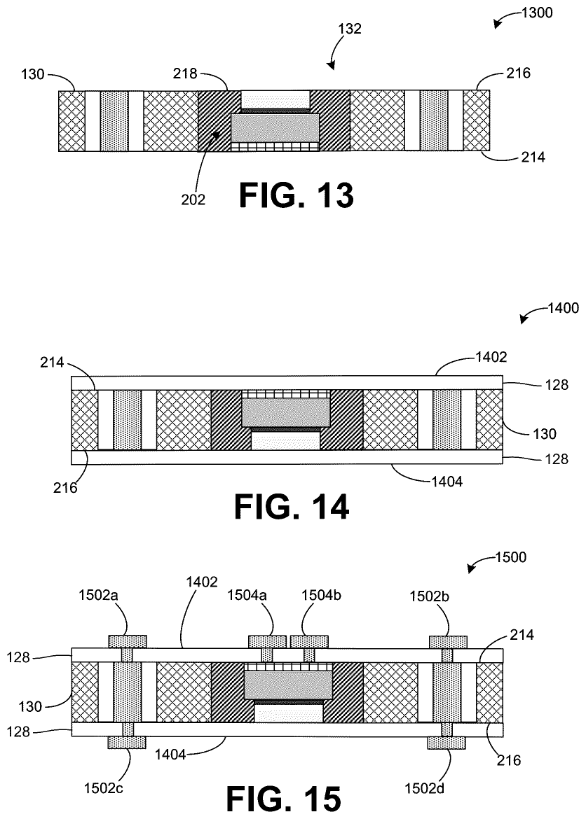

FIG. 13 is a cross-sectional view of an example eighth intermediate stage 1300 of the assembly/manufacturing of the package substrate 200 including the semiconductor component assembly 202. In some examples, the eighth intermediate stage 1300 occurs after the seventh intermediate stage 1200. In the eighth intermediate stage 1300, the carrier 320 has been removed. For example, the carrier 320 can be removed via a film removal method (e.g., etching, etc.). Additionally or alternatively, the core 130 can be removed (e.g., lifted, translated, etc.) from the carrier 320.

FIG. 14 is a cross-sectional view of an example ninth intermediate stage 1400 of the assembly/manufacturing of the package substrate 200 including the semiconductor component assembly 202. In some examples, the ninth intermediate stage 1400 occurs after the eighth intermediate stage 1300. In the ninth intermediate stage 1400, an example first build-up region portion 1402 (e.g., a first layer of dielectric material) of the build-up regions 128 of FIG. 1 has been deposited on the first core surface 214 of the core 130 and an example second build-up region portion 1404 (e.g., a second layer of dielectric material) of the build-up regions 128 of FIG. 1 has been deposited on the second core surface 216. In some examples, the build-up region portions 1402, 1404 are ABF that have been deposited on the core surfaces 214, 216 via lamination. In other examples, the build-up region portions 1402, 1404 can be disposed on the core surfaces 214, 216 in any other suitable deposition method (e.g., electroplating, CVD, ALD, PVD, etc.). In some examples, one or both of the build-up region portions 1402, 1404 can be absent and/or deposited after the ninth intermediate stage 1400. Additionally, in the illustrated example of FIG. 14, the core 130 and the semiconductor component assembly 202 has been flipped (e.g., rotated 180 degrees, etc.).

FIG. 15 is a cross-sectional view of an example tenth intermediate stage 1500 of the assembly/manufacturing of the package substrate 200 including the semiconductor component assembly 202. In some examples, the tenth intermediate stage 1500 occurs after the ninth intermediate stage 1400. In the tenth intermediate stage 1500, the core 130 has been further patterned to include an example first outer pad 1502a, an example second outer pad 1502b, an example third outer pad 1502c, an example fourth outer pad 1502d, an example first inner pad 1504a, and an example second inner pad 1504b. In some examples, the pads 1502a, 1502b, 1502c, 1502d, 1504a, 1504b can be formed via electroplating, atomic layer deposition (ALD), chemical vapor deposition (CVD), physical vapor deposition (PVD), lithography, and/or any other suitable materials. In some examples, the pads 1502a, 1502b, 1502c, 1502d, 1504a, 1504b can be part of the build-up layer interconnections 206. The inner pads 1504a, 1504b are electrically coupled to the circuitry component 212 and enable electric communication with the semiconductor component 134.

FIG. 16 is a block diagram of example operations 1600 for manufacturing a package substrate (e.g., the package substrate 200 of FIGS. 2 and 15, etc.) including semiconductor component assembly 202 of FIGS. 2, the semiconductor component assembly 300 of FIGS. 3A and 3B, the semiconductor component assembly 300 of FIGS. 3A and 3B, the semiconductor component assembly 400 semiconductor component assembly 400 of FIG. 4A, the semiconductor component assembly 416 of FIG. 4B, and/or the third semiconductor component assembly 420 of FIG. 4C. The example operations 1600 begin at block 1602, at which the core 130 is placed. For example, the core 130 of FIG. 1 can be placed on a wafer and/or die fabrication device. The point of fabrication after completion of block 1602 corresponds to the structure of the first intermediate stage 600 of FIG. 6.

At block 1604, the core 130 is patterned and/or the through core interconnections 204 are formed. For example, the core 130 can be patterned via laser etching, wet etching, drilling, and/or any other process. In some examples, the through core interconnections 204 can be formed in the core 130. The point of fabrication after completion of block 1604 corresponds to the structure of the second intermediate stage 700 of FIG. 7. At block 1606, the cavity 132 is drilled in the core 130. For example, the cavity 132 can be formed as a through hole in the cavity 132 via drilling. In other examples, the cavity 132 can be formed by any other suitable process (e.g., etching, etc.). The point of fabrication after completion of block 1606 corresponds to the structure of the third intermediate stage 800 of FIG. 8.

At block 1608, the carrier 320 is coupled to the core 130. For example, the carrier 320 can be coupled to the first core surface 214 and/or the second core surface 216 of the core 130. In some examples, the carrier 320 can be deposited on the core 130 as a temporary film. In other examples, the core 130 can be positioned on the carrier 320. The point of fabrication after completion of block 1608 corresponds to the structure of the fourth intermediate stage 900 of FIG. 9.

At block 1610, the semiconductor component 134 is placed on cavity 132 of the core 130 on the carrier 320. For example, the semiconductor component 134 can be disposed within the cavity 132, such that the electric components of the semiconductor component 134 (e.g., the circuitry component 212 of FIG. 2, the pads 304a, 304b, etc.) abut the carrier 320. In some examples, the semiconductor component 134 can be placed within the cavity 132 via mechanical deposition (e.g., via pick and place, via a chip shooter, etc.). The point of fabrication after completion of block 1610 corresponds to the structure of the fourth intermediate stage 900 of FIG. 9. At block 1612, the adhesive layer 208 is deposited on the semiconductor component 134 and/or the pedestal 210. For example, the adhesive layer 208 can be disposed on the semiconductor component 134 within the cavity 132 via a die attach film. Additionally or alternatively, the adhesive layer 208 can be disposed on the pedestal 210. The point of fabrication after completion of block 1612 corresponds to the structure of the fifth intermediate stage 1000 of FIG. 10.

At block 1614, the pedestal 210 is coupled to the semiconductor component 134 via an adhesive layer. For example, the pedestal 210 can be placed on the semiconductor component 134 via mechanical deposition (e.g., via pick and place, via a chip shooter, etc.). In other examples, the pedestal 210 can be coupled to the semiconductor component 134. In some examples, the larger planar area of the semiconductor component 134 can be used to align the pedestal 210 during the deposition on the semiconductor component 134. In other examples, the pedestal 210 can be fabricated on the semiconductor component 134. For example, the pedestal 210 can be deposited on the semiconductor component 134 in a plurality of layers (e.g., lamination, electroplating, CVD, PVD, ALD, etc.). The point of fabrication after completion of block 1614 corresponds to the structure of the sixth intermediate stage 1100 of FIG. 11.

At block 1616, the mold 218 is embedded within the cavity 132. For example, the mold 218 can be ABF deposited via lamination. In other examples, the mold 218 can be any other suitable materials. Additionally or alternatively, the mold 218 can be deposited via electroplating, atomic layer deposition (ALD), chemical vapor deposition (CVD), physical vapor deposition (PVD), etc. The point of fabrication after completion of block 1616 corresponds to the structure of the seventh intermediate stage 1200 of FIG. 12. At block 1618, the carrier 320 is removed from the core 130. For example, the carrier 320 can be removed via a film removal method (e.g., etching, etc.). Additionally or alternatively, the core 130 can be removed (e.g., lifted, translated, etc.) from the carrier 320. The point of fabrication after completion of block 1618 corresponds to the structure of the eighth intermediate stage 1300 of FIG. 13.

At block 1620, the build-up regions 128 and the build-up layer interconnections 206 are added to the core surfaces 214, 216 of the core 130. For example, the build-up region portions 1402, 1404 can be deposited on the core surfaces 214, 216 of the core 130, respectively. In some examples, the build-up region portions 1402, 1404 can be formed via ABF lamination. In other examples, the build-up region portions 1402, 1404 can be formed via any other material deposition process. Additionally or alternatively, after the deposition of the build-up region portions 1402, 1404, the build-up layer interconnections 206 can be formed. For example, the pads 1502a, 1502b, 1502c, 1502d, 1504a, 1504b of FIG. 5 can be formed via electroplating, atomic layer deposition (ALD), chemical vapor deposition (CVD), physical vapor deposition (PVD), lithography, and/or any other suitable materials. The point of fabrication after completion of block 1620 corresponds to the structure of the tenth intermediate stage 1500 of FIG. 15.

Although the example operations 1600 are described with reference to the flowchart illustrated in FIG. 16, many other methods of assembling/manufacturing a package substrate including the semiconductor component assembly 202 of FIG. 2, the semiconductor component assembly 300 of FIGS. 3A and 3B, the semiconductor component assembly 300 of FIGS. 3A and 3B, the semiconductor component assembly 400 semiconductor component assembly 400 of FIG. 4A, the semiconductor component assembly 416 of FIG. 4B, and/or the third semiconductor component assembly 420 of FIG. 4C may alternatively be used. For example, the order of execution of the blocks may be changed, and/or some of the blocks described may be changed, eliminated, or combined.

FIG. 17 is a block diagram of example operations 1700 for manufacturing a package substrate including the semiconductor component assembly 502 of FIGS. 5A and 5B. The operations 1700 begin at block 1702, at which a core of a package substrate is positioned. At block 1704, the core is patterned and/or core interconnections are formed. At block 1706, a cavity is drilled in the core. At block 1708, a carrier film is deposited on the core. The execution of blocks 1702, 1704, 1706, 1708 can be executed in a manner similar to the execution of blocks 1602, 1604, 1606, 1608 of the operations 1600 of FIG. 16, respectively. In other examples, the execution of blocks 1702, 1704, 1706, 1708 can be performed via any other suitable semiconductor manufacturing processes.

At block 1710, the pedestal 506 is provided on the carrier 320. For example, the pedestal 506 can be fabricated and mechanically disposed within the cavity 132 within the carrier 320 (e.g., via pick and place, etc.). In some such examples, the pedestal 506 can be coupled to the carrier 320 via an adhesive film (e.g., the second adhesive layer 508, etc.). In other examples, the pedestal 506 can be fabricated within the cavity 132. For example, the pedestal 506 can be fabricated on the carrier 320. For example, the pedestal 506 can be deposited on the carrier 320 in a plurality of layers (e.g., lamination, electroplating, CVD, PVD, ALD, etc.). At block 1712, an adhesive layer is deposited on the pedestal 506. For example, the first adhesive layer 504 of FIG. 5A can be deposited on the pedestal 506. Additionally or alternatively, the encapsulate layer 524 can be deposited within the cavity 132 and onto the pedestal 506.

At block 1714, the semiconductor component 302 is coupled to the pedestal 506 via the adhesive layer (e.g., the adhesive layer 504, the encapsulate layer 524, etc.). For example, the semiconductor component 302 can be mechanically disposed on the pedestal 506 (e.g., via pick and place, via a chip shooter, etc.). In some examples, the larger planar area of the pedestal 506 can be used to align the semiconductor component 302 during the deposition on the pedestal 506. In some examples, the semiconductor component 302 can be coupled to the pedestal 506 prior to the deposition of the pedestal on the carrier 320 (e.g., the execution of block 1714 occurs prior to the execution of block 1708, etc.).

At block 1716, a mold is deposited within the cavity. At block 1718, the carrier 320 is removed. At block 1720, interconnects to the semiconductor component are formed. The execution of blocks 1716, 1718, 1720 can be executed in a manner similar to the execution of blocks 1616, 1618, 1620 of the operations 1600 of FIG. 16, respectively. In other examples, the execution of blocks 1716, 1718, 1720 can be performed via any other suitable semiconductor manufacturing processes. After the execution of block 1720, the operations 1700 end.

Although the example operations 1700 are described with reference to the flowchart illustrated in FIG. 17, many other methods of assembling/manufacturing a package substrate including the semiconductor component assembly 502 of FIGS. 5A and 5B may alternatively be used. For example, the order of execution of the blocks may be changed, and/or some of the blocks described may be changed, eliminated, or combined. For example, in some examples, the semiconductor assembly 502 can be assembled prior to the deposition of the semiconductor component 302 and the pedestal 506 within the cavity 132.

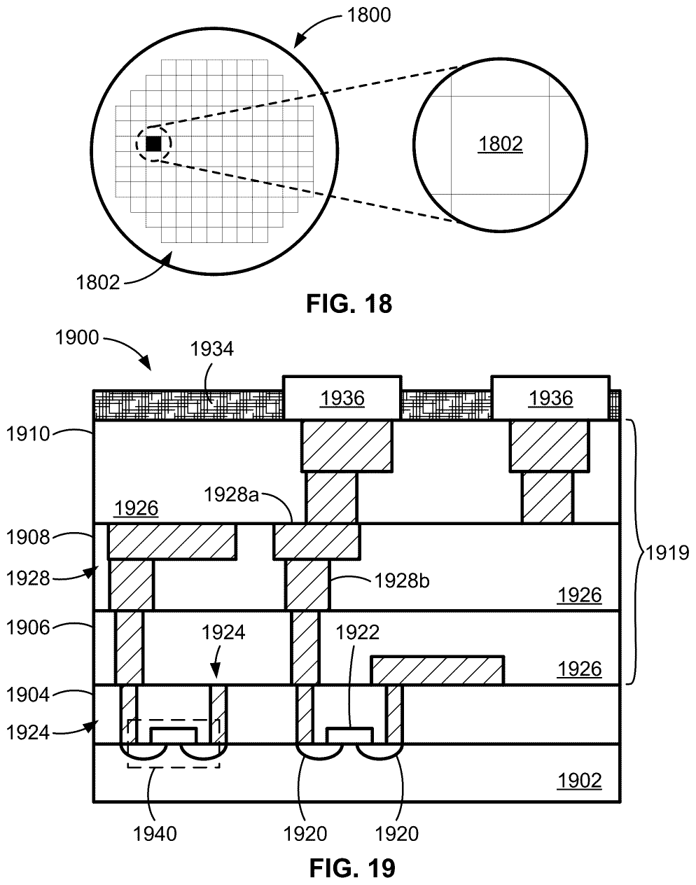

FIG. 18 is a top view of a wafer 1800 and dies 1802 that may be included in the package substrates 200, 308, 500, 521. The wafer 1800 may be composed of semiconductor material and may include one or more dies 1802 having IC structures formed on a surface of the wafer 1800. Each of the dies 1802 may be a repeating unit of a semiconductor product that includes any suitable IC. After the fabrication of the semiconductor product is complete, the wafer 1800 may undergo a singulation process in which the dies 1802 are separated from one another to provide discrete “chips” of the semiconductor product. The die 1802 may include one or more transistors (e.g., some of the transistors 1940 of FIG. 19, discussed below), supporting circuitry to route electrical signals to the transistors, passive components (e.g., signal traces, resistors, capacitors, or inductors), and/or any other IC components. In some examples, the wafer 1800 or the die 1802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1802. For example, a memory array formed by multiple memory devices may be formed on a same die 1802 as processor circuitry or other logic that is configured to store information in the memory devices or execute instructions stored in the memory array. The example package substrates 200, 308, 500, 521 disclosed herein may be manufactured using a die-to-wafer assembly technique in which some dies 106, 108 are attached to a wafer 1800 that include others of the dies 106, 108, and the wafer 1800 is subsequently singulated.

FIG. 19 is a cross-sectional side view of an IC device 1900 that may be included in the example package substrates 200, 308, 500, 521 (e.g., in any one of the package substrate 110). One or more of the IC devices 1900 may be included in one or more dies 1802 (FIG. 18). The IC device 1900 may be formed on a die substrate 1902 (e.g., the wafer 1800 of FIG. 18) and may be included in a die (e.g., the die 1802 of FIG. 18). The die substrate 1902 may be a semiconductor substrate composed of semiconductor material systems including, for example, n-type or p-type materials systems (or a combination of both). The die substrate 1902 may include, for example, a crystalline substrate formed using a bulk silicon or a silicon-on-insulator (SOI) substructure. In some examples, the die substrate 1902 may be formed using alternative materials, which may or may not be combined with silicon, which include but are not limited to germanium, indium antimonide, lead telluride, indium arsenide, indium phosphide, gallium arsenide, or gallium antimonide. Further materials classified as group II-VI, III-V, or IV may also be used to form the die substrate 1902. Although a few examples of materials from which the die substrate 1902 may be formed are described here, any material that may serve as a foundation for an IC device 1900 may be used. The die substrate 1902 may be part of a singulated die (e.g., the dies 1802 of FIG. 18) or a wafer (e.g., the wafer 1800 of FIG. 18).

The IC device 1900 may include one or more device layers 1904 disposed on the die substrate 1902. The device layer 1904 may include features of one or more transistors 1940 (e.g., metal oxide semiconductor field-effect transistors (MOSFETs)) formed on the die substrate 1902. The device layer 1904 may include, for example, one or more source and/or drain (S/D) regions 1920, a gate 1922 to control current flow in the transistors 1940 between the S/D regions 1920, and one or more S/D contacts 1924 to route electrical signals to/from the S/D regions 1920. The transistors 1940 may include additional features not depicted for the sake of clarity, such as device isolation regions, gate contacts, and the like. The transistors 1940 are not limited to the type and configuration depicted in FIG. 19 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 1940 may include a gate 1922 formed of at least two layers, a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 1940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some examples, when viewed as a cross-section of the transistor 1940 along the source-channel-drain direction, the gate electrode may consist of a U-shaped structure that includes a bottom portion substantially parallel to the surface of the die substrate 1902 and two sidewall portions that are substantially perpendicular to the top surface of the die substrate 1902. In other examples, at least one of the metal layers that form the gate electrode may simply be a planar layer that is substantially parallel to the top surface of the die substrate 1902 and does not include sidewall portions substantially perpendicular to the top surface of the die substrate 1902. In other examples, the gate electrode may consist of a combination of U-shaped structures and planar, non-U-shaped structures. For example, the gate electrode may consist of one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some examples, a plurality of spacer pairs may be used; for instance, two pairs, three pairs, or four pairs of sidewall spacers may be formed on opposing sides of the gate stack.

The S/D regions 1920 may be formed within the die substrate 1902 adjacent to the gate 1922 of each transistor 1940. The S/D regions 1920 may be formed using an implantation/diffusion process or an etching/deposition process, for example. In the former process, dopants such as boron, aluminum, antimony, phosphorous, or arsenic may be ion-implanted into the die substrate 1902 to form the S/D regions 1920. An annealing process that activates the dopants and causes them to diffuse farther into the die substrate 1902 may follow the ion-implantation process. In the latter process, the die substrate 1902 may first be etched to form recesses at the locations of the S/D regions 1920. An epitaxial deposition process may then be carried out to fill the recesses with material that is used to fabricate the S/D regions 1920. In some implementations, the S/D regions 1920 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 1920 may be formed using one or more alternate semiconductor materials such as germanium or a group III-V material or alloy. In further examples, one or more layers of metal and/or metal alloys may be used to form the S/D regions 1920.

Electrical signals, such as power and/or input/output (I/O) signals, may be routed to and/or from the devices (e.g., transistors 1940) of the device layer 1904 through one or more interconnect layers disposed on the device layer 1904 (illustrated in FIG. 19 as interconnect layers 1906-1910). For example, electrically conductive features of the device layer 1904 (e.g., the gate 1922 and the S/D contacts 1924) may be electrically coupled with the interconnect structures 1928 of the interconnect layers 1906-1910. The one or more interconnect layers 1906-1910 may form a metallization stack (also referred to as an “ILD stack”) 1919 of the IC device 1900.

The interconnect structures 1928 may be arranged within the interconnect layers 1906-1910 to route electrical signals according to a wide variety of designs (in particular, the arrangement is not limited to the particular configuration of interconnect structures 1928 depicted in FIG. 19). Although a particular number of interconnect layers 1906-1910 is depicted in FIG. 19, examples of the present disclosure include IC devices having more or fewer interconnect layers than depicted.

In some examples, the interconnect structures 1928 may include lines 1928a and/or vias 1928b filled with an electrically conductive material such as a metal. The lines 1928a may be arranged to route electrical signals in a direction of a plane that is substantially parallel with a surface of the die substrate 1902 upon which the device layer 1904 is formed. For example, the lines 1928a may route electrical signals in a direction in and out of the page from the perspective of FIG. 19. The vias 1928b may be arranged to route electrical signals in a direction of a plane that is substantially perpendicular to the surface of the die substrate 1902 upon which the device layer 1904 is formed. In some examples, the vias 1928b may electrically couple lines 1928a of different interconnect layers 1906-1910 together.

The interconnect layers 1906-1910 may include a dielectric material 1926 disposed between the interconnect structures 1928, as shown in FIG. 19. In some examples, the dielectric material 1926 disposed between the interconnect structures 1928 in different ones of the interconnect layers 1906-1910 may have different compositions; in other examples, the composition of the dielectric material 1926 between different interconnect layers 1906-1910 may be the same.

A first interconnect layer 1906 (referred to as Metal 1 or “M1”) may be formed directly on the device layer 1904. In some examples, the first interconnect layer 1906 may include lines 1928a and/or vias 1928b, as shown. The lines 1928a of the first interconnect layer 1906 may be coupled with contacts (e.g., the S/D contacts 1924) of the device layer 1904.

A second interconnect layer 1908 (referred to as Metal 2 or “M2”) may be formed directly on the first interconnect layer 1906. In some examples, the second interconnect layer 1908 may include vias 1928b to couple the lines 1928a of the second interconnect layer 1908 with the lines 1928a of the first interconnect layer 1906. Although the lines 1928a and the vias 1928b are structurally delineated with a line within each interconnect layer (e.g., within the second interconnect layer 1908) for the sake of clarity, the lines 1928a and the vias 1928b may be structurally and/or materially contiguous (e.g., simultaneously filled during a dual-damascene process) in some examples.

A third interconnect layer 1910 (referred to as Metal 3 or “M3”) (and additional interconnect layers, as desired) may be formed in succession on the second interconnect layer 1908 according to similar techniques and configurations described in connection with the second interconnect layer 1908 or the first interconnect layer 1906. In some examples, the interconnect layers that are “higher up” in the metallization stack 1919 in the IC device 1900 (i.e., further away from the device layer 1904) may be thicker.

The IC device 1900 may include a solder resist material 1934 (e.g., polyimide or similar material) and one or more conductive contacts 1936 formed on the interconnect layers 1906-1910. In FIG. 19, the conductive contacts 1936 are illustrated as taking the form of bond pads. The conductive contacts 1936 may be electrically coupled with the interconnect structures 1928 and configured to route the electrical signals of the transistor(s) 1940 to other external devices. For example, solder bonds may be formed on the one or more conductive contacts 1936 to mechanically and/or electrically couple a chip including the IC device 1900 with another component (e.g., a circuit board). The IC device 1900 may include additional or alternate structures to route the electrical signals from the interconnect layers 1906-1910; for example, the conductive contacts 1936 may include other analogous features (e.g., posts) that route the electrical signals to external components.

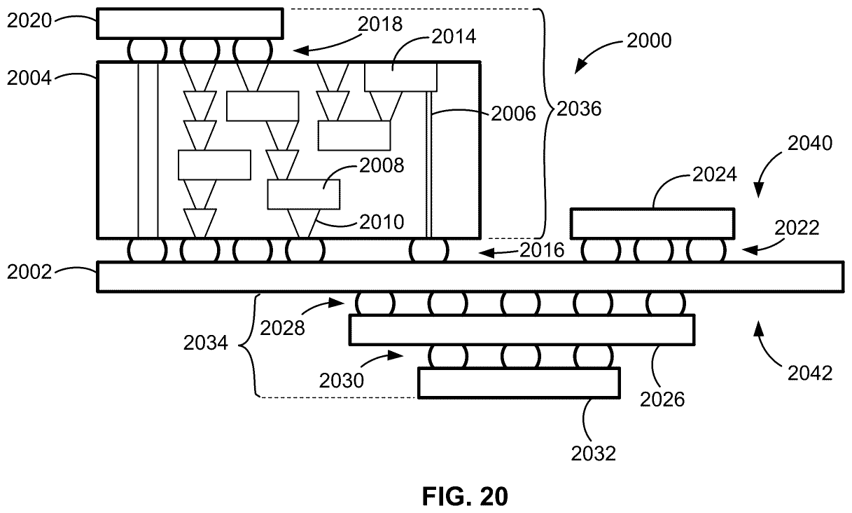

FIG. 20 is a cross-sectional side view of an IC device assembly 2000 that may include the package substrates 200, 308, 500, 521 disclosed herein. In some examples, the IC device assembly corresponds to the package substrates 200, 308, 500, 521. The IC device assembly 2000 includes a number of components disposed on a circuit board 2002 (which may be, for example, a motherboard). The IC device assembly 2000 includes components disposed on a first face 2040 of the circuit board 2002 and an opposing second face 2042 of the circuit board 2002; generally, components may be disposed on one or both faces 2040 and 2042. Any of the IC packages discussed below with reference to the IC device assembly 2000 may take the form of the example package substrates 200, 308, 500, 521 of FIGS. 2, 3, and 5.

In some examples, the circuit board 2002 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2002. In other examples, the circuit board 2002 may be a non-PCB substrate. In some examples, the circuit board 2002 may be, for example, the circuit board 102 of FIG. 1.

The IC device assembly 2000 illustrated in FIG. 20 includes a package-on-interposer structure 2036 coupled to the first face 2040 of the circuit board 2002 by coupling components 2016. The coupling components 2016 may electrically and mechanically couple the package-on-interposer structure 2036 to the circuit board 2002, and may include solder balls (as shown in FIG. 20), male and female portions of a socket, an adhesive, an underfill material, and/or any other suitable electrical and/or mechanical coupling structure.

The package-on-interposer structure 2036 may include an IC package 2020 coupled to an interposer 2004 by coupling components 2018. The coupling components 2018 may take any suitable form for the application, such as the forms discussed above with reference to the coupling components 2016. Although a single IC package 2020 is shown in FIG. 20, multiple IC packages may be coupled to the interposer 2004; indeed, additional interposers may be coupled to the interposer 2004. The interposer 2004 may provide an intervening substrate used to bridge the circuit board 2002 and the IC package 2020. The IC package 2020 may be or include, for example, a die (the die substrate 1902 of FIG. 19), an IC device (e.g., the IC device 2000 of FIG. 20), or any other suitable component. Generally, the interposer 2004 may spread a connection to a wider pitch or reroute a connection to a different connection. For example, the interposer 2004 may couple the IC package 2020 (e.g., a die) to a set of BGA conductive contacts of the coupling components 2016 for coupling to the circuit board 2002. In the example illustrated in FIG. 20, the IC package 2020 and the circuit board 2002 are attached to opposing sides of the interposer 2004; in other examples, the IC package 2020 and the circuit board 2002 may be attached to a same side of the interposer 2004. In some examples, three or more components may be interconnected by way of the interposer 2004.

In some examples, the interposer 2004 may be formed as a PCB, including multiple metal layers separated from one another by layers of dielectric material and interconnected by electrically conductive vias. In some examples, the interposer 2004 may be formed of an epoxy resin, a fiberglass-reinforced epoxy resin, an epoxy resin with inorganic fillers, a ceramic material, or a polymer material such as polyimide. In some examples, the interposer 2004 may be formed of alternate rigid or flexible materials that may include the same materials described above for use in a semiconductor substrate, such as silicon, germanium, and other group III-V and group IV materials. The interposer 2004 may include metal interconnects 2008 and vias 2010, including but not limited to through-silicon vias (TSVs) 2006. The interposer 2004 may further include embedded devices 2014, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2004. The package-on-interposer structure 2036 may take the form of any of the package-on-interposer structures known in the art.

The IC device assembly 2000 may include an IC package 2024 coupled to the first face 2040 of the circuit board 2002 by coupling components 2022. The coupling components 2022 may take the form of any of the examples discussed above with reference to the coupling components 2016, and the IC package 2024 may take the form of any of the examples discussed above with reference to the IC package 2020.

The IC device assembly 2000 illustrated in FIG. 20 includes a package-on-package structure 2034 coupled to the second face 2042 of the circuit board 2002 by coupling components 2028. The package-on-package structure 2034 may include a first IC package 2026 and a second IC package 2032 coupled together by coupling components 2030 such that the first IC package 2026 is disposed between the circuit board 2002 and the second IC package 2032. The coupling components 2028, 2030 may take the form of any of the examples of the coupling components 2016 discussed above, and the IC packages 2026, 2032 may take the form of any of the examples of the IC package 2020 discussed above. The package-on-package structure 2034 may be configured in accordance with any of the package-on-package structures known in the art.

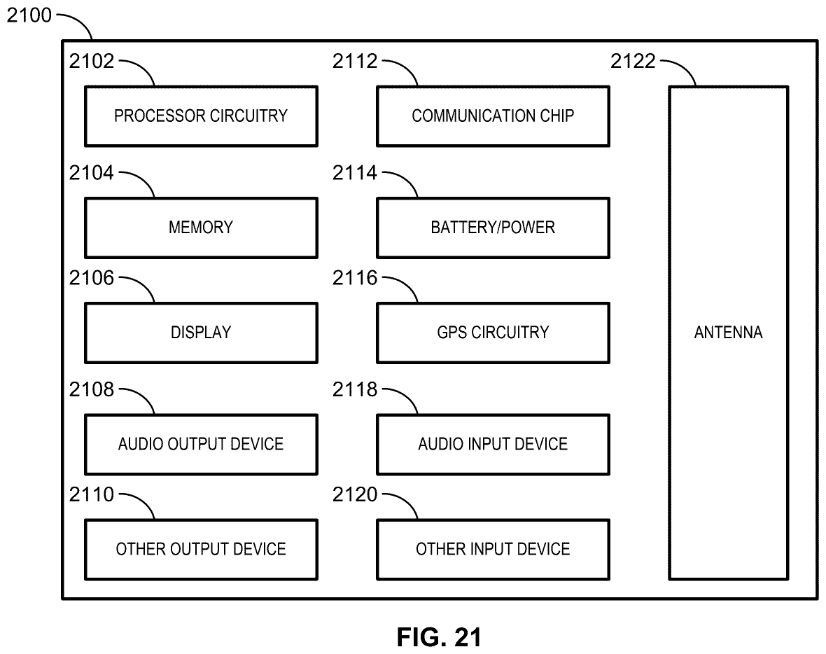

FIG. 21 is a block diagram of an example electrical device 2100 that may include one or more of the example package substrates 200, 308, 500, 521 of FIGS. 2, 3, 5, and 15. For example, any suitable ones of the components of the electrical device 2100 may include one or more of the device assemblies 2100, IC devices 2000, or die substrate 1902 disclosed herein, and may be arranged in the example package substrates 200, 308, 500, 521. A number of components are illustrated in FIG. 21 as included in the electrical device 2100, but any one or more of these components may be omitted or duplicated, as suitable for the application. In some examples, some or all of the components included in the electrical device 2100 may be attached to one or more motherboards. In some examples, some or all of these components are fabricated onto a single system-on-a-chip (SoC) die.

Additionally, in various examples, the electrical device 2100 may not include one or more of the components illustrated in FIG. 21, but the electrical device 2100 may include interface circuitry for coupling to the one or more components. For example, the electrical device 2100 may not include a display 2106, but may include display interface circuitry (e.g., a connector and driver circuitry) to which a display 2106 may be coupled. In another set of examples, the electrical device 2100 may not include an audio input device 2118 (e.g., microphone) or an audio output device 2108 (e.g., a speaker, a headset, earbuds, etc.), but may include audio input or output device interface circuitry (e.g., connectors and supporting circuitry) to which an audio input device 2118 or audio output device 2108 may be coupled.

The electrical device 2100 may include a processor circuitry 2102 (e.g., one or more processing devices). As used herein, the term “processing device” or “processor” may refer to any device or portion of a device that processes electronic data from registers and/or memory to transform that electronic data into other electronic data that may be stored in registers and/or memory. The processor circuitry 2102 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 2100 may include a memory 2104, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 2104 may include memory that shares a die with the processor circuitry 2102. This memory may be used as cache memory and may include embedded dynamic random access memory (eDRAM) or spin transfer torque magnetic random access memory (STT-MRAM).

In some examples, the electrical device 2100 may include a communication chip 2112 (e.g., one or more communication chips). For example, the communication chip 2112 may be configured for managing wireless communications for the transfer of data to and from the electrical device 2100. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 2112 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2505 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2112 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2112 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2112 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2112 may operate in accordance with other wireless protocols in other examples. The electrical device 2100 may include an antenna 2122 to facilitate wireless communications and/or to receive other wireless communications (such as AM or FM radio transmissions).

In some examples, the communication chip 2112 may manage wired communications, such as electrical, optical, or any other suitable communication protocols (e.g., the Ethernet). As noted above, the communication chip 2112 may include multiple communication chips. For instance, a first communication chip 2112 may be dedicated to shorter-range wireless communications such as Wi-Fi or Bluetooth, and a second communication chip 2112 may be dedicated to longer-range wireless communications such as global positioning system (GPS), EDGE, GPRS, CDMA, WiMAX, LTE, EV-DO, or others. In some examples, a first communication chip 2112 may be dedicated to wireless communications, and a second communication chip 2112 may be dedicated to wired communications.

The electrical device 2100 may include battery/power circuitry 2114. The battery/power circuitry 2114 may include one or more energy storage devices (e.g., batteries or capacitors) and/or circuitry for coupling components of the electrical device 2100 to an energy source separate from the electrical device 2100 (e.g., AC line power).

The electrical device 2100 may include a display 2106 (or corresponding interface circuitry, as discussed above). The display 2106 may include any visual indicators, such as a heads-up display, a computer monitor, a projector, a touchscreen display, a liquid crystal display (LCD), a light-emitting diode display, or a flat panel display.

The electrical device 2100 may include an audio output device 2108 (or corresponding interface circuitry, as discussed above). The audio output device 2108 may include any device that generates an audible indicator, such as speakers, headsets, or earbuds.

The electrical device 2100 may include an audio input device 2118 (or corresponding interface circuitry, as discussed above). The audio input device 2118 may include any device that generates a signal representative of a sound, such as microphones, microphone arrays, or digital instruments (e.g., instruments having a musical instrument digital interface (MIDI) output).

The electrical device 2100 may include GPS circuitry 2116. The GPS circuitry 2116 may be in communication with a satellite-based system and may receive a location of the electrical device 2100, as known in the art.

The electrical device 2100 may include any other output device 2110 (or corresponding interface circuitry, as discussed above). Examples of the other output device 2110 may include an audio codec, a video codec, a printer, a wired or wireless transmitter for providing information to other devices, or an additional storage device.

The electrical device 2100 may include any other input device 2120 (or corresponding interface circuitry, as discussed above). Examples of the other input device 2120 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 2100 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 2100 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor component (e.g., a transistor), a semiconductor die containing a semiconductor component, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor component) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor components are often used in orientation different than their orientation during fabrication. Thus, when referring to a semiconductor component (e.g., a transistor), a semiconductor die containing a semiconductor component, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example an integrated circuit may be implemented as one or more of an ASIC, an FPGA, a chip, a microchip, programmable circuitry, a semiconductor substrate coupling multiple circuit elements, a system on chip (SoC), etc.

Example 1 includes a package substrate for an integrated circuit package, the package substrate comprising a core having a first surface, a second surface, and a cavity formed in the first surface, a semiconductor component disposed in the cavity, and a pedestal disposed in the cavity, the pedestal having a third surface coupled to the semiconductor component, and a fourth surface adjacent to the first surface, the pedestal dimensioned such that a first thickness of the pedestal and semiconductor is substantially equal to a second thickness of the core.

Example 2 includes the package substrate of example 1, wherein the semiconductor component includes a deep trench capacitor die.

Example 3 includes the package substrate of example 1, further including an adhesive layer disposed between the semiconductor component and the third surface, the adhesive layer coupling the pedestal to the semiconductor component.

Example 4 includes the package substrate of example 3, wherein the adhesive layer includes an encapsulant.

Example 5 includes the package substrate of example 3, wherein the pedestal has a first planar area, the semiconductor component has a second planar area, and the first planar area is greater than the second planar area, the first planar area parallel to the second planar area.

Example 6 includes the package substrate of example 5, wherein the adhesive layer is a first adhesive layer, further including a second adhesive layer coupled to the fourth surface, the second adhesive layer having a fifth surface substantially flush with the second surface.

Example 7 includes the package substrate of example 1, wherein the pedestal has a first planar area, the semiconductor component has a second planar area, and the first planar area is smaller than the second planar area.

Example 8 includes the package substrate of example 1, wherein a depth of the cavity is greater than 800 micrometers.

Example 9 includes the package substrate of example 1, wherein the pedestal includes a dummy silicon die.

Example 10 includes the package substrate of example 1, wherein semiconductor component is a first semiconductor component and the pedestal is a second semiconductor component.

Example 11 includes an integrated circuit package comprising a semiconductor die, a package substrate supporting the semiconductor die, the package substrate including a core defining a cavity, and a semiconductor component assembly disposed within the cavity, the semiconductor component assembly including a semiconductor component including a first surface, and a spacer including a second surface, the first surface facing away from the spacer, the second surface facing away from the semiconductor component, the spacer dimensioned such that a distance between the first and second surfaces is substantially equal to a thickness of the core.

Example 12 includes the integrated circuit package of example 11, wherein the spacer includes a silicon die.

Example 13 includes the integrated circuit package of example 11, wherein the spacer includes a deep trench capacitor die.

Example 14 includes the integrated circuit package of example 11, wherein the semiconductor component has a first thickness of less than 800 micrometers and the core has a second thickness of at least 900 micrometers.

Example 15 includes the integrated circuit package of example 11, wherein the semiconductor component has a first width and the spacer has a second width, the first width different than the second width.

Example 16 includes the integrated circuit package of example 15, wherein the second width is greater than the first width.

Example 17 includes a method comprising drilling a cavity in a core of a package substrate, the core having a first surface and a second surface, the cavity extending between the first surface and the second surface, positioning a carrier on the first surface, placing a semiconductor component within the cavity, the semiconductor component supported by the carrier, the semiconductor component coupled to a pedestal, the semiconductor component substantially flush with at least one of the first surface or the second surface, and embedding a mold in the cavity, the mold surrounding the semiconductor component.

Example 18 includes the method of example 17, further including placing the pedestal on the carrier, depositing an adhesive layer on the pedestal, and wherein the placing of the semiconductor component within the cavity includes coupling the semiconductor component to the pedestal via the adhesive layer, the pedestal has a first width, the semiconductor component has a second width, and the first width is greater than the second width.

Example 19 includes the method of example 17, further including coupling the pedestal to a third surface of the semiconductor component, the placing of the semiconductor component within the cavity includes coupling a fourth surface of the semiconductor component to the carrier, the second surface opposite the first surface, the pedestal has a first width, the semiconductor component has a second width, and the first width is less than the second width.

Example 20 includes the method of example 17, further including coupling the semiconductor component to the pedestal before the placing of the semiconductor component within the cavity. The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A package substrate for an integrated circuit package, the package substrate comprising:
a core having:
a first surface;
a second surface; and
a cavity formed in the first surface;
a semiconductor component disposed in the cavity; and
a pedestal disposed in the cavity, the pedestal having:
a third surface coupled to the semiconductor component; and
a fourth surface adjacent to the first surface, the pedestal dimensioned such that a first thickness of the pedestal and semiconductor is substantially equal to a second thickness of the core.

2. The package substrate of claim 1, wherein the semiconductor component includes a deep trench capacitor die.

3. The package substrate of claim 1, further including an adhesive layer disposed between the semiconductor component and the third surface, the adhesive layer coupling the pedestal to the semiconductor component.

4. The package substrate of claim 3, wherein the adhesive layer includes an encapsulant.

5. The package substrate of claim 3, wherein the pedestal has a first planar area, the semiconductor component has a second planar area, and the first planar area is greater than the second planar area, the first planar area parallel to the second planar area.

6. The package substrate of claim 5, wherein the adhesive layer is a first adhesive layer, further including a second adhesive layer coupled to the fourth surface, the second adhesive layer having a fifth surface substantially flush with the second surface.

7. The package substrate of claim 1, wherein the pedestal has a first planar area, the semiconductor component has a second planar area, and the first planar area is smaller than the second planar area.

8. The package substrate of claim 1, wherein a depth of the cavity is greater than 800 micrometers.

9. The package substrate of claim 1, wherein the pedestal includes a dummy silicon die.

10. The package substrate of claim 1, wherein semiconductor component is a first semiconductor component and the pedestal is a second semiconductor component.

11. An integrated circuit package comprising:
a semiconductor die;
a package substrate supporting the semiconductor die, the package substrate including a core defining a cavity; and
a semiconductor component assembly disposed within the cavity, the semiconductor component assembly including:
a semiconductor component including a first surface; and
a spacer including a second surface, the first surface facing away from the spacer, the second surface facing away from the semiconductor component, the spacer dimensioned such that a distance between the first and second surfaces is substantially equal to a thickness of the core.

12. The integrated circuit package of claim 11, wherein the spacer includes a silicon die.

13. The integrated circuit package of claim 11, wherein the spacer includes a deep trench capacitor die.

14. The integrated circuit package of claim 11, wherein the semiconductor component has a first thickness of less than 800 micrometers and the core has a second thickness of at least 900 micrometers.

15. The integrated circuit package of claim 11, wherein the semiconductor component has a first width and the spacer has a second width, the first width different than the second width.

16. The integrated circuit package of claim 15, wherein the second width is greater than the first width.

17. A method comprising:
drilling a cavity in a core of a package substrate, the core having a first surface and a second surface, the cavity extending between the first surface and the second surface;
positioning a carrier on the first surface;
placing a semiconductor component within the cavity, the semiconductor component supported by the carrier, the semiconductor component coupled to a pedestal, the semiconductor component substantially flush with at least one of the first surface or the second surface; and
embedding a mold in the cavity, the mold surrounding the semiconductor component.

18. The method of claim 17, further including:
placing the pedestal on the carrier;
depositing an adhesive layer on the pedestal; and
wherein the placing of the semiconductor component within the cavity includes coupling the semiconductor component to the pedestal via the adhesive layer, the pedestal has a first width, the semiconductor component has a second width, and the first width is greater than the second width.

19. The method of claim 17, further including coupling the pedestal to a third surface of the semiconductor component, the placing of the semiconductor component within the cavity includes coupling a fourth surface of the semiconductor component to the carrier, the second surface opposite the first surface, the pedestal has a first width, the semiconductor component has a second width, and the first width is less than the second width.

20. The method of claim 17, further including coupling the semiconductor component to the pedestal before the placing of the semiconductor component within the cavity.
